(19) United States
(12) Patent Application Publication
(10) Pub. No.: US 2009/0231012 A1
(43) Pub. Date: Sep. 17, 2009

(54) External voltage level down circuit

(75) Inventor: Bong Hwa Jeong, Seoul (KR)

Correspondence Address: COOPER & DUNHAM, LLP, 30 Rockefeller Plaza, 20th Floor, NEW YORK, NY, 10112, US

(73) Assignee: Hynix Semiconductor Inc.

(21) Appl. No.: 12/317,942

(22) Filed: Dec. 31, 2008

(30) Foreign Application Priority Data
Mar. 17, 2008 (KR) 10-2008-0024581

(51) Int. Cl. H03L 5/00

(52) U.S. Cl. 327/333

(57) ABSTRACT

An external voltage level down circuit includes a first level down unit which receives a first control signal enabled in a power down mode and down-converts a level of a first external voltage, a control signal generating unit which generates a second control signal in response to the down-converted level of the first external voltage, and a second level down unit which receives the second control signal and down-converts a level of a second external voltage.

### TECHNICAL FIELD

The present disclosure relates to a semiconductor memory device, and more particularly to an external voltage level down circuit capable of preventing malfunctions due to the reversion of external voltage levels in a deep power down mode.

### BACKGROUND

Generally, a semiconductor memory device operates in an active state or in a stand-by state. When a semiconductor memory device is in an active state, circuits within a chip perform operations of outputting information to an exterior or inputting it into an interior. On the other hand, when the semiconductor memory device is in a stand-by state, all of the current paths, except a minimized number of circuits typically that are needed for entering an active state, are isolated (that is, from the current paths) to minimize power consumption in the chip. However, if the semiconductor memory device maintains the stand-by state for a long time, currents are continuously consumed by the circuits enabled to enter the active state, resulting in unnecessary power consumption.

Accordingly, a deep power down mode capable of minimizing current consumption by isolating all current paths of a chip to reduce current consumption in a stand-by state is provided in a prior art. In the deep power down mode, the external voltage provided to internal circuits is level-downed to prevent unnecessary operations of the internal circuits in the semiconductor memory device. Such a circuit of level-downing an external voltage to a ground voltage VSS is called an external voltage level down circuit.

Referring to FIG. 1, a structure of an external voltage level down circuit used in a semiconductor memory device using an external voltage VDD of one level is discussed. The operation of the external voltage level down circuit is as follows.

First, a control signal generating unit 10 which receives a deep power down mode command DPD that is enabled when entering a deep power down mode, generates a control signal CON. Next, a level down unit 12 level-downs the external voltage VDD to a ground voltage VSS in response to the control signal CON.

Meanwhile, some semiconductor memory devices are provided with external voltages of different levels to operate. For example, since the LPDDR2 supports the VDD operation of low level, it is provided with external voltages of different levels to operate.

The structure of the external voltage level down circuit used in the semiconductor memory device which operates by being provided with external voltages of different levels as described above is illustrated in FIG. 2. Such an external voltage level down circuit as described above also level-downs the external voltages VDD1 and VDD2 to the ground voltage VSS by the control signal CON generated in response to the deep power down mode command DPD.

A conventional external voltage level down circuit collectively level-downs the external voltages to the ground voltage VSS according to the control signal CON without consideration of the different levels of the external voltages in the deep power down mode. Therefore, the different levels of the external voltages may be reversed, causing malfunctions.

### SUMMARY

In an aspect of the present disclosure, an external voltage level down circuit is provided capable of preventing malfunctions due to reversion of external voltage levels from a deep power down mode, by sequentially down-converting the external voltages from a lower voltage level to a higher voltage level.

In an embodiment, an external voltage level down circuit includes a first level down unit configured to receive a first control signal enabled in a power down mode and to down-convert a level of a first external voltage, a control signal generating unit for generating a second control signal in response to the down-converted level of the first external voltage, and a second level down unit configured to receive the second control signal and to down-convert a level of a second external voltage.

In another embodiment, an external voltage level down circuit includes a first control signal generating unit for generating a first control signal enabled in a power down mode, a first level down unit which configured to receive the first control signal and to down-convert a level of a first external voltage, a second control signal generating unit for generating a second control signal in response to the down-converted level of the first external voltage, a delay unit for delaying the second control signal for a predetermined interval, and a second level down unit configured to receive an output signal of the delay unit and to down-convert a level of a second external voltage.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 and 2 are block diagrams showing the structure of an external voltage level down circuit according to a prior art;

FIG. 3 is a block diagram showing the structure of an external voltage level down circuit according to an embodiment of the present disclosure;

FIG. 4 is a circuit diagram showing a first level down unit included in the external voltage level down circuit shown in FIG. 3;

FIG. 5 is a circuit diagram showing a second level down unit included in the external voltage level down circuit shown in FIG. 3; and

FIG. 6 is a block diagram showing the structure of an external voltage level down circuit according to another embodiment of the present disclosure.

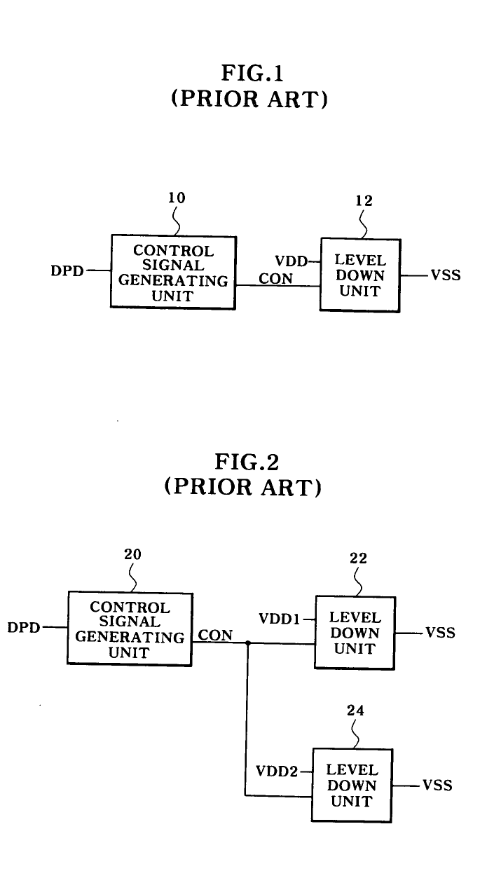

### DETAILED DESCRIPTION OF PREFERRED EMBODIMENTS

Hereinafter, examples and embodiments of the present disclosure will be described with reference to accompanying drawings. However, the examples and embodiments are for illustrative purposes only and are not intended to limit the scope of the invention.

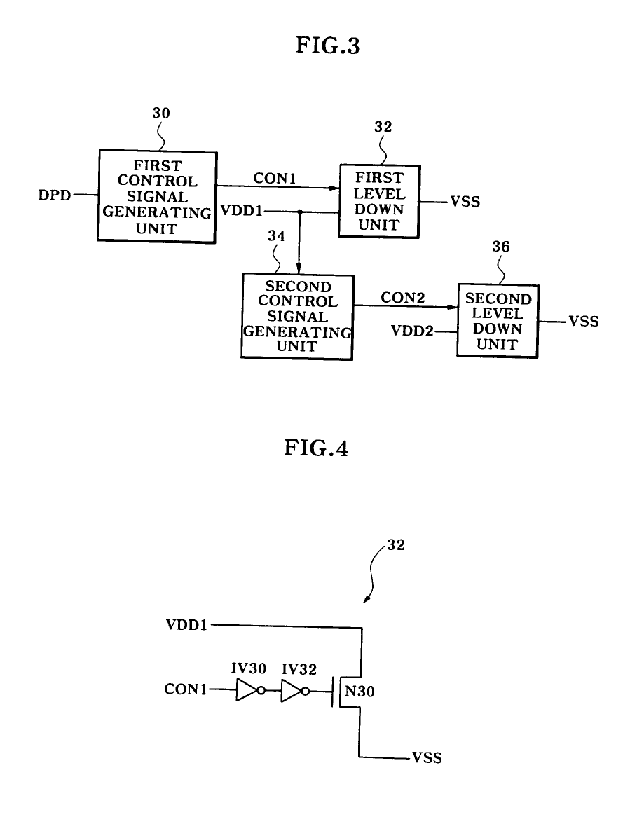

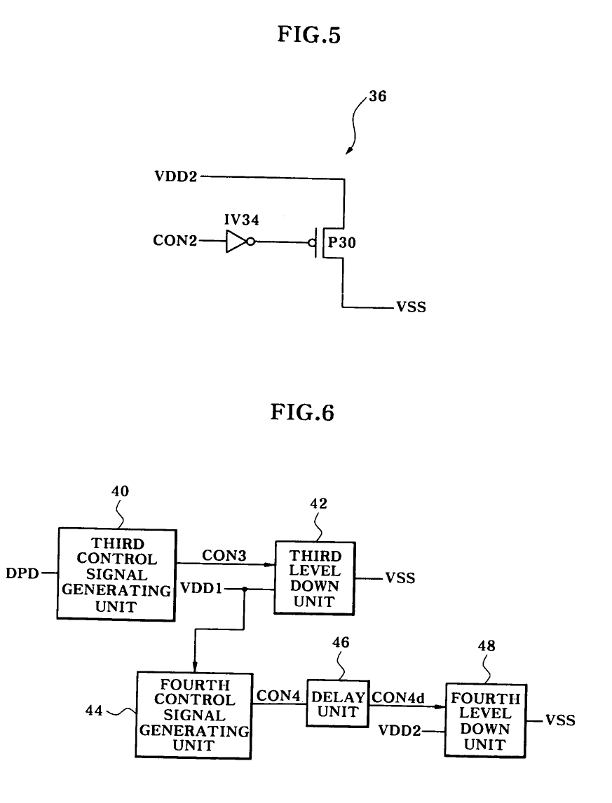

FIG. 3 is a block diagram showing the structure of an external voltage level down circuit according to an embodiment of the present disclosure, FIG. 4 is a circuit diagram showing a first level down unit included in the external voltage level down circuit shown in FIG. 3, and FIG. 5 is a circuit diagram showing a second level down unit included in the external voltage level down circuit shown in FIG. 3.

The external voltage level down circuit of the present disclosure comprises a first control signal generating unit 30, a first level down unit 32, a second control signal generating unit 34 and a second level down unit 36.

The first control signal generating unit 30 inputs a deep power down mode command DPD enabled when entering a deep power down mode and generates a first control signal CON1 enabled to a high level.

Referring to FIG. 4, the first level down unit 32 comprises a NMOS transistor N30 which is connected between a first external voltage VDD1 and a ground voltage VSS and is turned on in response to the first control signal CON1. The first level down unit 32 inputs the first control signal CON1 enabled to a high level and then down-converts a level of the first external voltage VDD1 to the ground voltage VSS level.

The second control signal generating unit 34 inputs the first external voltage VDD1 and generates a second control signal CON2 which is enabled to a high level when the first external voltage VDD1 is down-converted to the ground voltage VSS.

Referring to FIG. 5, the second level down unit 36 comprises a PMOS transistor P30 which is connected between a second external voltage VDD2 and the ground voltage VSS and is turned on in response to the second control signal CON2. The second level down unit 36 inputs the second control signal CON2 enabled to a high level and down-converts a level of the second external voltage VDD2 to the ground voltage VSS level. Here, the second external voltage VDD2 is set to be higher than the first external voltage VDD1.

Operation of the external voltage level down circuit configured as described above will be discussed with reference to FIGS. 3 to 5.

First, when the deep power down mode command DPD is input to enter the deep power down mode, the first control signal generating unit 30 generates the first control signal CON1 of high level.

The first control signal CON1 of high level is input to the first level down unit 32 to turn on the NMOS transistor N30, thereby down-converting a level of the first external voltage VDD1 to the ground voltage VSS level.

If the first external voltage VDD1 is down-converted to the ground voltage VSS level, the second control signal generating unit 34 generates the second control signal CON2 of high level.

The second control signal CON2 of high level is input to the second level down unit 36 to turn on the PMOS transistor P30, thereby down-converting a level of the second external voltage VDD2 to the ground voltage VSS level.

In summary, in the case that the semiconductor memory device operating by first and second external voltages VDD1 and VDD2 enters the deep power down mode, the external voltage level down circuit of the present disclosure down-converts a level of the first external voltage VDD1 of comparatively low level to the ground voltage VSS level and then down-converts a level of the second external voltage VDD2 to a level of the ground voltage VSS. As described above, by sequentially down-converting the external voltages from a lower level, the external voltage level down circuit of the present disclosure can prevent malfunctions due to reversion of the external voltage levels from the deep power down mode.

FIG. 6 is a block diagram showing the external voltage level down circuit according to another embodiment of the present disclosure.

The external voltage level down circuit of the present disclosure comprises a third control signal generating unit 40, a third level down unit 42, a fourth control signal generating unit 44, a delay unit 46 and a fourth level down unit 48.

The third control signal generating unit 40 inputs a deep power down mode command DPD enabled when entering the deep power down mode and generates a third control signal CON3 enabled to a high level.

The third level down unit 42 inputs the third control signal CON3 enabled to a high level and down-converts a level of a first external voltage VDD1 to a ground voltage VSS level.

The fourth control signal generating unit 44 inputs the first external voltage VDD1 and generates a fourth control signal CON4 enabled to a high level when the first external voltage VDD1 is down-converted to the ground voltage VSS level.

The delay unit 46 inputs the fourth control signal CON4 and delays it for a predetermined interval, to generate a fourth delay control signal CON4d. The delay unit 46 is required to control the timing for transmitting the fourth control signal CON4 to the fourth level down unit 48.

The fourth level down unit 48 inputs the fourth delay control signal CON4d enabled to a high level through the delay unit 46 and down-converts a level of a second external voltage VDD2 to the ground voltage VSS level. Here, the second external voltage VDD2 is set to be higher than the first external voltage VDD1.

Operation of the external voltage level down circuit configured as described above will be discussed with reference to FIG. 6.

First, if the deep power down mode command DPD is input to enter the deep power down mode, the third control signal generating unit 40 generates the third control signal CON3 of high level.

The third control signal CON3 of high level is input to the third level down unit 42, thereby causing the first external voltage VDD1 to be down-converted to the ground voltage VSS level.

If the first external voltage VDD1 is down-converted to the ground voltage VSS level, the fourth control signal generating unit 44 generates the fourth control signal CON4 of high level.

The fourth control signal CON4 of high level is delayed for a predetermined interval through the delay unit 46 and then is input to the fourth level down unit 48, thereby causing the second external voltage VDD2 to be down-converted to the ground voltage VSS level.

As described above, by sequentially down-converting the external voltages to a lower voltage level, the external voltage level down circuit of the present disclosure can prevent malfunctions due to reversion of the external voltage levels in the deep power down mode. In addition, the external voltage level down circuit of the present disclosure includes the delay unit 46, enabling control of the level-down timing of the second external voltage VDD2. For example, the more the delay interval of the delay unit 46 is increased, the more the level-down timing of the second external voltage VDD2 is slowed.

While examples and embodiments of the present invention have been described for illustrative purposes, those skilled in the art will appreciate that various modifications, additions and substitutions are possible, without departing from the scope and spirit of the disclosure and the accompanying claims.

The present disclosure claims priority to Korean application 10-2008-0024581, filed on Mar. 17, 2008, the entire contents of which are incorporated herein by reference.

What is claimed is:

1. An external voltage level down circuit comprising:
a first level down unit configured to receive a first control signal enabled in a power down mode and to down-convert a level of a first external voltage;
a control signal generating unit for generating a second control signal in response to the down-converted level of the first external voltage; and
a second level down unit configured to receive the second control signal and to down-convert a level of a second external voltage.

2. The external voltage level down circuit of claim 1, wherein the level of the first external voltage is lower than the level of the second external voltage.

3. The external voltage level down circuit of claim 1, wherein the second control signal generated by the control signal generating unit is enabled when the first external voltage has the down-converted level.

4. The external voltage level down circuit of claim 1, wherein the first level down unit includes a switch which connects the first external voltage to a ground voltage in response to the first control signal.

5. The external voltage level down circuit of claim 4, wherein the switch is an NMOS transistor.

6. The external voltage level down circuit of claim 1, wherein the second level down unit includes a switch which connects the second external voltage to a ground voltage in response to the second control signal.

7. The external voltage level down circuit of claim 6, wherein the switch is a PMOS transistor.

8. An external voltage level down circuit comprising:
a first control signal generating unit for generating a first control signal enabled in a power down mode;
a first level down unit configured to receive the first control signal and to down-convert a level of a first external voltage;
a second control signal generating unit for generating a second control signal in response to the down-converted level of the first external voltage;
a delay unit for delaying the second control signal for a predetermined interval; and
a second level down unit configured to receive an output signal of the delay unit and to down-convert a level of a second external voltage.

9. The external voltage level down circuit of claim 8, wherein level of the first external voltage is lower than the level of the second external voltage.

10. The external voltage level down circuit of claim 8, wherein the second control signal generated by the second control signal generating unit is enabled when the first external voltage has the down-converted level.

11. The external voltage level down circuit of claim 8, wherein the first level down unit includes a switch which connects the first external voltage to a ground voltage in response to the first control signal.

12. The external voltage level down circuit of claim 8, wherein the second level down unit includes a switch which connects the second external voltage to a ground voltage in response to an output signal of the delay unit.
